(19) United States
(12) Patent Application Publication
(10) Pub. No.: US 2012/0236522 A1
(43) Pub. Date: Sep. 20, 2012

(54) Method for forming an EMI shielding layer on an Electronic System

(75) Inventors: Jen-Shiun HUANG, HSINCHU (TW); Feng-Chuan YEH, HSINCHU (TW); Yi-Ju LI, HSINCHU (TW)

(73) Assignee: E INK HOLDINGS INC., HSINCHU (TW)

(21) Appl. No.: 13/295,109

(22) Filed: Nov. 14, 2011

(30) Foreign Application Priority Data
Mar. 14, 2011 (TW) 100108551

(51) Int. Cl. H05K 7/02; B32B 37/12; B05D 5/12

(52) U.S. Cl. 361/760; 427/96.3; 427/523; 156/182

(57) ABSTRACT

The present invention provides a method for forming a shielding layer on a sensor board. The sensor board includes an antenna array element. The sensor board is integrated into an electronic system. The method includes using a physical vapor deposition process to form the shielding layer on the sensor board to shield the sensor board from an electromagnetic signal generated by the electronic system, wherein the shielding layer and the antenna array element are respectively formed on two opposite surfaces of the sensor board.

### RELATED APPLICATIONS

This application claims priority to Taiwan Application Serial Number 100108551, filed Mar. 14, 2011, which is herein incorporated by reference.

### BACKGROUND

1. Field of Invention

The present invention relates to a method for forming an EMI shielding layer, and more particularly to a method for forming an EMI shielding layer on an Electronic System.

2. Description of Related Art

With the improvement of techniques for manufacture and design, many new display apparatus is developed, and the electronic paper display device presents many advantages including lower energy consumption, longer lifetime, and smaller size.

Typically, three main sensing control technologies are used in electronic paper display including resistive sensing technology, capacitance sensing technology and electromagnetic sensing technology. Both circuits for performing the resistive sensing and the capacitance sensing have to be adhered on the top surface of the electronic paper display to sense a touch event. Because the electronic paper display has to reflect the light to display content, the circuits formed on the top surface would block partial light into the electronic paper display. The display quality is reduced. However, the circuit for performing the electromagnetic sensing is built in the back of the electronic paper display. That is, this circuit would not block the light into the electronic paper display. Therefore, the electromagnetic sensing technology has been extensively used in the electronic paper display.

Typically, a sensor board using the electromagnetic sensing technology includes a substrate with an antenna array, a control circuit for calculating the touch position and a sensing pen. The sensing pen is a transceiver and the substrate with the antenna array is a receiver. When a user uses the sensing pen to touch the electronic paper display, magnetic flux is changed. A micro-controller can detect the change of the magnetic flux to calculate the touch position. However, because electromagnetic sensing technology uses the electromagnetic induction to detect the touch position, the electromagnetic signal would affect the correctness of detecting result.

Therefore, when a sensor board using the electromagnetic sensing technology is integrated into the electronic paper display, a shielding layer is formed on this sensor board to shield the substrate with an antenna array from the electromagnetic signal generated by the electronic paper display. However, typically, the shielding layer is adhered to the sensor board by hand. Such processing method not only is very complex but also costs high.

### SUMMARY

An object of the present invention is to provide a method to form a shielding layer on a sensor board that is integrated into an electronic paper display. A physical vapor deposition process is used to form the shielding layer in the sensor board to replace the typical manual process of adhering a shielding layer on the sensor board.

An embodiment of the present invention provides a method for forming a shielding layer on a sensor board. The sensor board includes an antenna array element. The sensor board is integrated into an electronic system. The method includes using a physical vapor deposition process to form the shielding layer on the sensor board to shield the sensor board from an electromagnetic signal generated by the electronic system, and the shielding layer and the antenna array element are respectively formed on two opposite surfaces of the sensor board.

An embodiment of the present invention provides a method for forming a shielding layer on a sensor board. The sensor board includes an antenna array element. The sensor board is integrated into an electronic system. The method includes using a physical vapor deposition process to deposit at least a metal layer on a mylar to serve as the shielding layer, and adhering the shielding layer to the sensor board to shield the sensor board from an electromagnetic signal generated by the electronic system, and the shielding layer and the antenna array element are respectively formed on two opposite surfaces of the sensor board.

An embodiment of the present invention provides a display. The display includes an electronic system including a panel and a control board, a sensor board disposed between the panel and the control board and having an antenna array element, a shielding layer disposed between the sensor board and the control board to shield the sensor board from an electromagnetic signal generated by the control board, the shielding layer and the antenna array element are respectively formed on two opposite surfaces of the sensor board, and the shielding layer is made by using a physical vapor deposition process.

Accordingly, the shielding layer is formed in a sensor board by a physical vapor deposition process to shield the antenna array of the sensor board from an electromagnetic signal generated by a main electronic system. The method replaces the typical manual process of adhering a shielding layer on the sensor board. Therefore, the cost is down.

### BRIEF DESCRIPTION OF THE DRAWINGS

In order to make the foregoing as well as other aspects, features, advantages, and embodiments of the present invention more apparent, the accompanying drawings are described as follows:

FIG. 1 illustrates an explosion diagram of an electronic paper display with a sensor board using the electromagnetic sensing technology; and

FIG. 2 is a schematic diagram of a sputtering apparatus.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

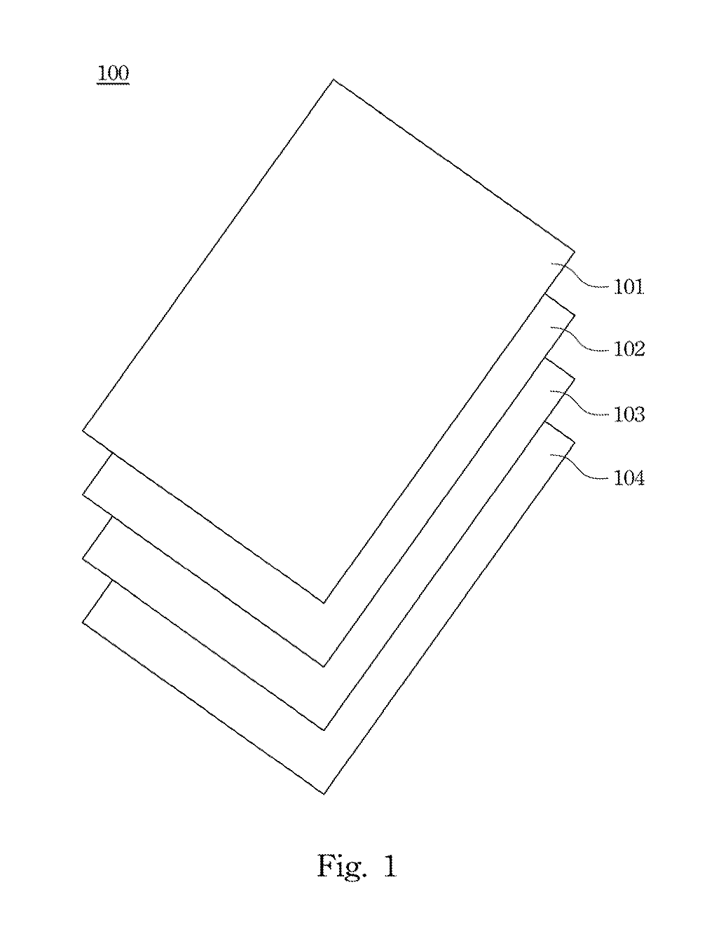

FIG. 1 illustrates an explosion diagram of an electronic paper display with a sensor board using the electromagnetic sensing technology. The electronic paper display 100 includes an electronic paper panel 101, a sensor board 102 using the electromagnetic sensing technology, a shielding layer 103 and a main control board 104 below the electronic paper pane 101. The sensor board 102 disposed between the electronic paper panel 101 and the main control board 104 includes a substrate with an antenna array element. The sensor board 102 receives a signal generated by an electromagnetic pen pressing the electronic paper panel 101 to define the coordinate of the pressing position. The main control board 104 is disposed under the sensor board 102. A micro-controller and input-output elements are located on the main control board 104 to control the operation of the electronic paper display 100. Electromagnetic signals are generated when the micro-controller and input-output elements work. For shielding the sensor board 102 from the electromagnetic signals, a shielding layer 103 is formed between the sensor board 102 and the main control board 104. The shielding layer 103 and the antenna array element are respectively formed on two opposite surfaces of the sensor board 102. The shielding layer 103 is formed on the sensor board 102 by a physical vapor deposition process. Physical vapor deposition (PVD) is a variety of vacuum deposition and is a general term used to describe any of a variety of methods to deposit thin films by the condensation of a vaporized form of the material onto various surfaces. The coating method involves purely physical processes such as vacuum evaporation process or a sputtering process rather than involving a chemical reaction at the surface. In the vacuum evaporation process, the source material is evaporated in a vacuum. The vacuum allows vapor particles to travel directly to the target object (substrate), where they condense back to a solid state. In sputtering process, atoms are ejected from a solid target material due to bombardment of the target by energetic particles. The incident ions set off collision cascades in the target. When such cascades recoil and reach the target surface with an energy above the surface binding energy, an atom can be ejected. Sputtered atoms ejected into the gas phase are not in their thermodynamic equilibrium state, and tend to deposit on all surfaces in the vacuum chamber. A substrate (such as a wafer) placed in the chamber will be coated with a thin film. Sputtering usually uses an argon plasma.

In the following embodiment, a sputtering process is used to form a shielding layer 103 on the sensor board 102. However, other kinds of physical vapor deposition process, such as an evaporation process and an electroplating process, can be also used in the present invention to form the shielding layer 103.

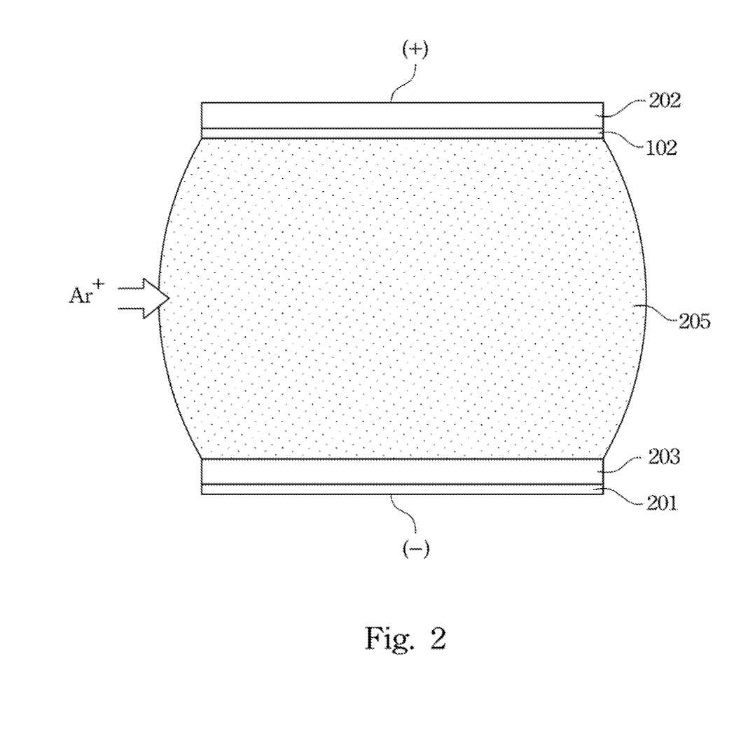

FIG. 2 is a schematic diagram of a sputtering apparatus. Before the sputtering process is started, a protection layer is formed in the sensor board 102 to cover the regions where it is not necessary to form the shielding layer thereon. Then, the sensor board 102 is placed on a plate 202 that is coupled to a positive electrode. A vacuum adsorption technique is used to fix the sensor board 102 on the plate 202. The target material 203 is placed on the plate 201 that is coupled to a negative electrode. Similarly, a vacuum adsorption technique is used to fix the target material 203 on the plate 201. Next, the chamber is pumped down to process pressure. Sputtering starts when a negative charge is applied to the target material 203 causing a plasma 205. Positive charged gas ions (Ar+) generated in the plasma region are attracted to the negative biased target plate 201 at a very high speed. This collision creates a momentum transfer and ejects atomic size particles from the target material 203. These particles traverse the chamber and are deposited as a shielding layer 103 onto the surface of the sensor board 102.

In an embodiment, all absorbing magnetic material can be used to serve as the target material 203 to deposit absorbing magnetic thin films as a shielding layer onto the surface of the sensor board 102. In a preferred embodiment, the shielding layer is a multi-layer metal thin film and a mylar, such as a Fe—Al mylar, a Fe—Ni mylar or an Inox-Al mylar. The thickness of the shielding layer is from 1 um to 1 mm, the preferred thickness is from 1 um to 1 mm, and the best thickness is from 10 um to 0.3 mm.

According to an embodiment, the shielding layer 103 is an Inox-Al mylar. When a sputtering process is started, the sensor board 102 is fixed in the plate 202. Next, the target material 203, Inox, is placed in the plate 201. Then, ions (Ar+) hit the target material 203 at a very high speed to eject atomic size particles from the target material 203. These particles traverse the chamber and are deposited onto the surface of the sensor board 102 to form an Inox material layer. Next, the target material 203, Al, is placed in the plate 201. Then, ions (Ar+) hit the target material 203 at a very high speed to eject atomic size particles from the target material 203. These particles traverse the chamber and are deposited onto the surface of the sensor board 102 to form an Al material layer over the Inox material layer. Finally, a mylar is adhered to the Inox-Al layer to form an Inox-Al mylar layer as a shielding layer 103.

In another embodiment, the shielding layer 103 is a Fe—Al mylar. When a sputtering process is started, the sensor board 102 is fixed in the plate 202. Next, the target material 203, Fe, is placed in the plate 201. Then, ions (Ar+) hit the target material 203 at a very high speed to eject atomic size particles from the target material 203. These particles traverse the chamber and are deposited onto the surface of the sensor board 102 to form a Fe material layer. Next, the target material 203, Al, is placed in the plate 201. Then, ions (Ar+) hit the target material 203 at a very high speed to eject atomic size particles from the target material 203. These particles traverse the chamber and are deposited onto the surface of the sensor board 102 to form an Al material layer over the Fe material layer. Finally, a mylar is adhered to the Fe—Al layer to form a Fe—Al mylar layer as a shielding layer 103.

In a further embodiment, the multi-layer metal thin film are directly deposited in a mylar to form an Inox-Al mylar layer, a Fe—Al mylar or a Fe—Ni mylar layer to serve as a shielding layer 103. Then, the shielding layer 103 is adhered to the sensor board 102.

For example, the shielding layer 103 is an Inox-Al mylar. When a sputtering process is started, the mylar 102 is fixed in the plate 202. Next, the target material 203, Al, is placed in the plate 201. Then, ions (Ar+) hit the target material 203 at a very high speed to eject atomic size particles from the target material 203. These particles traverse the chamber and are deposited onto the surface of the sensor board 102 to form an Al material layer over the mylar. Next, the target material 203, Inox, is placed in the plate 201. Then, ions (Ar+) hit the target material 203 at a very high speed to eject atomic size particles from the target material 203. These particles traverse the chamber and are deposited onto the surface of the sensor board 102 to form an Inox material layer over the Al material layer and the mylar for forming an Inox-Al mylar layer as a shielding layer 103.

On the other hand, the shielding layer 103 is a Fe—Al mylar. When a sputtering process is started, the mylar is fixed in the plate 202. Next, the target material 203, Al is placed in the plate 201. Then, ions (Ar+) hit the target material 203 at a very high speed to eject atomic size particles from the target material 203. These particles traverse the chamber and are deposited onto the surface of the sensor board 102 to form an Al material layer. Next, the target material 203, Fe, is placed in the plate 201. Then, ions (Ar+) hit the target material 203 at a very high speed to eject atomic size particles from the target material 203. These particles traverse the chamber and are deposited onto the surface of the sensor board 102 to form a Fe material layer over the Al material layer and the mylar for forming a Fe—Al mylar layer as a shielding layer 103.

Accordingly, the shielding layer is formed in a sensor board by a physical vapor deposition process to shield the antenna array of the sensor board from an electromagnetic signal generated by a main system. The method replaces is the typical manual process of adhering a shielding layer on the sensor board. Therefore, the cost is down.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method for forming a shielding layer on a sensor board, wherein the sensor board includes an antenna array element and is integrated into an electronic system, comprising:
using a physical vapor deposition process to form the shielding layer on the sensor board to shield the sensor board from an electromagnetic signal generated by the electronic system, wherein the shielding layer and the antenna array element are respectively formed on two opposite surfaces of the sensor board.

2. The method of claim 1, wherein the physical vapor deposition process is an evaporation process or a sputtering process.

3. The method of claim 1, wherein the shielding layer is made by an Fe—Al mylar, a Fe—Ni mylar, or an Inox-Al mylar.

4. The method of claim 1, wherein a thickness of the shielding layer is from 10 um to 0.3 mm.

5. The method of claim 1, wherein a thickness of the shielding layer is from 1 um to 1 mm.

6. The method of claim 1, wherein the electronic system is an electronic paper display including a panel and a control board, the sensor board is disposed between the panel and the control board, and the shielding layer is disposed between the sensor board and the control board to shield the sensor board from the electromagnetic signal generated by the control board.

7. A method for forming a shielding layer on a sensor board, wherein the sensor board includes an antenna array element and is integrated into an electronic system, comprising:
using a physical vapor deposition process to deposit at least a metal layer on a mylar to serve as the shielding layer; and
adhering the shielding layer to the sensor board to shield the sensor board from an electromagnetic signal generated by the electronic system, wherein the shielding layer and the antenna array element are respectively formed on two opposite surfaces of the sensor board.

8. The method of claim 7, wherein the physical vapor deposition process is an evaporation process or a sputtering process.

9. The method of claim 7, wherein the shielding layer is made by an Fe—Al mylar, an Fe—Ni mylar, or an Inox-Al mylar.

10. The method of claim 1, wherein a thickness of the shielding layer is from 10 um to 0.3 mm.

11. The method of claim 1, wherein a thickness of the shielding layer is from 1 um to 1 mm.

12. A display comprising:
a panel;
a control board disposed below the panel;
a sensor board disposed between the panel and the control board and having an antenna array element; and
a shielding layer disposed between the sensor board and the control board to shield the sensor board from an electromagnetic signal generated by the control board, wherein the shielding layer and the antenna array element are respectively formed on two opposite surfaces of the sensor board and the shielding layer is made by using a physical vapor deposition process.

13. The method of claim 12, wherein the physical vapor deposition process is an evaporation process or a sputtering process.

14. The method of claim 12, wherein the shielding layer is a conductive layer.

15. The method of claim 14, wherein the shielding layer is made by an Fe—Al mylar, an Fe—Ni mylar, or an Inox-Al mylar.

16. The method of claim 12, wherein a thickness of the shielding layer is from 10 um to 0.3 mm.

17. The method of claim 12, wherein a thickness of the shielding layer is from 1 um to 1 mm.
